(19) United States
(12) Patent Application Publication
(10) Pub. No.: US 2015/0138562 A1
(43) Pub. Date: May 21, 2015

(54) WAVELENGTH-VARIABLE LASER INCLUDING SOA AND OPTICAL COHERENCE TOMOGRAPHY APPARATUS INCLUDING THE LASER

(71) Applicant: CANON KABUSHIKI KAISHA, Tokyo (JP)

(72) Inventor: Takeshi Uchida, Hiratsuka-shi (JP)

(73) Assignee: Canon Kabushiki Kaisha, Tokyo (JP)

(21) Appl. No.: 14/402,867

(22) PCT Filed: May 21, 2013
(86) PCT No.: PCT/JP2013/064563

§ 371 Date: Nov. 21, 2014

(30) Foreign Application Priority Data
May 22, 2012 (JP) 2012-116552

(51) Int. Cl. H01S 5/34; H01S 5/50; G01B 9/02

(52) U.S. Cl. CPC H01S 5/34; G01B 9/02004; G01B 9/02091; H01S 5/509
USPC 356/479; 372/50.22; 372/45.01

(57) ABSTRACT

Provided is a wavelength-variable laser including an SOA which controls not a shape of a gain spectrum itself in the SOA but a shape of a gain spectrum obtained in the entire SOA to enable inhibition of output fluctuations. The wavelength-variable laser including an SOA includes: a wavelength selection mechanism for selectively reflecting a wavelength; an SOA for amplifying light, the SOA being configured to reflect light that enters a first end facet by a second end facet opposite to the first facet and to cause light amplified in an active layer to exit from the first facet; and a reflecting member provided outside the SOA, the reflecting member forming a resonator in a pair with the second facet, in which the second facet has a multilayer film to control of a shape of gain spectrum obtained in the entire SOA, the multilayer film having a reflectance depending on wavelength.

### TECHNICAL FIELD

The present invention relates to a wavelength-variable laser including an SOA which is a semiconductor optical amplifier for amplifying light.

### BACKGROUND ART

A semiconductor optical amplifier (SOA) for amplifying light is mainly used for amplifying a signal in optical communication and the like.

Applications other than this include an application in which an SOA is incorporated into and used in a resonator structure including an optical component and an optical fiber.

In this case, the SOA is used for induced amplification for laser oscillation. Such a laser adapted for laser operation with a resonator provided outside an SOA which is a semiconductor optical amplifier is hereinafter referred to as an external resonator type laser.

A general edge emitting type laser is small in size and low in cost. The structure of a semiconductor chip in an SOA is similar to that of a general edge emitting type laser. Therefore, if the purpose is only to realize laser oscillation, the edge emitting type laser is more advantageous from the viewpoint of the size and the cost.

On the other hand, the external resonator type laser has an advantage over the edge emitting type laser in that wavelength variable operation can be realized relatively easily.

Further, an optical system for wavelength selection can be provided in the external resonator, and the degree of design flexibility thereof is higher than that of a mechanism which may be incorporated into the semiconductor. Therefore, the external resonator type laser is excellent in wavelength variable range size, wavelength variable stability, and reproducibility in the wavelength variability.

For example, in PTL 1, a wavelength scanning type laser light source (wavelength-variable laser) using a wavelength selection mechanism in the external is disclosed.

In this wavelength-variable laser, the wavelength selection mechanism includes a grating, a condensing lens, a rotary disk, and a reflecting mirror for reflecting light which passes through a hole formed in a part of the rotary disk.

The wavelength variable mechanism uses the fact that the diffraction angle of light diffracted by the grating varies depending on the wavelength, and the above-mentioned members are arranged so that only light which is diffracted at a certain angle by the grating is reflected to return to the grating.

The wavelength-variable laser is operated by returning only a certain wavelength to the SOA in this way. Further, among such SOAs, an SOA having a structure in which a single quantum well or multiple quantum wells having the same structure are introduced is known in NPL 1.

By the way, in a system which applies the wavelength-variable laser, there is a case in which optical output and the like are desired not to fluctuate when the wavelength changes.

For example, in an example in which the wavelength-variable laser is applied to optical coherence tomography (OCT), a tomogram is formed from change over time in optical output which is obtained through an interference system during a wavelength sweep, and thus, even when the amount of emitted light is monitored and the output fluctuations are canceled, it is preferred that the change in optical output of the laser be smaller from the viewpoint of the S/N ratio and the like.

On the other hand, the dependence of the gain of the SOA used for OCT on wavelength is not sufficiently low, and, when the wavelength sweep range is relatively broad (30 nm or more), the dependence on wavelength of the magnitude of the induced amplification in an active layer, that is, of the gain becomes conspicuous. As a result, in the case of a wavelength sweep by an external resonator, a problem arises that the optical output thereof fluctuates significantly.

In relation to such a problem, a mechanism of determining the shape of a gain spectrum in an SOA is further described.

In a structure as in NPL 1 described above, in which a single quantum well or multiple quantum wells having the same structure are introduced, the gain spectrum of the quantum well(s) depends on the energy distribution of carriers in the quantum well(s), that is, the so-called Fermi-Dirac distribution multiplied by the density of states of the quantum well(s), specifically, the rectangular shape of the density of states.

These two are determined according to the quantum mechanics and the physical properties of the material, and thus, it is impossible to artificially and arbitrarily control the shape.

Therefore, while the emission wavelength and the magnitude of the gain can be changed by the material and the layer structure, the shape of the gain spectrum in the SOA cannot be arbitrarily changed.

### CITATION LIST

### Patent Literature

PTL 1: Japanese Patent Application Laid-Open No. 2008-98395

### Non Patent Literature

NPL 1: A. T. Semenov, et al., ELECTRONICS LETTERS, Vol. 32, No. 3, pp. 255, 1996
NPL 2: Optics Express, Vol. 14, Issue 20, pp. 9299-9306, 2006

### SUMMARY OF INVENTION

### Technical Problem

The present invention has been made in view of the above-mentioned problem, and an object of the present invention is to provide a wavelength-variable laser including an SOA which controls not a shape of a gain spectrum of a quantum well itself used in the SOA but a shape of a gain spectrum obtained in the entire SOA device to enable inhibition of optical output fluctuations of the laser when the wavelength changes.

According to an exemplary embodiment of the present invention, there is provided a wavelength-variable laser including a semiconductor optical amplifier, the wavelength-variable laser including: a wavelength selection mechanism for selectively reflecting a wavelength; an SOA which is a semiconductor optical amplifier for amplifying light, the SOA being configured to reflect light that enters a first end facet by a second end facet opposite to the first end facet and to cause light amplified in an active layer to exit from the first end facet side again; and a reflecting member provided outside the SOA, the reflecting member forming a resonator in a pair with the second end facet for reflecting the light which enters, in which the second end facet of the SOA, which is on a side of reflecting the light, has a multilayer film formed thereon to enable control of a shape of a gain spectrum obtained in the entire SOA, the multilayer film having a reflectance which depends on wavelength.

Further, according to another exemplary embodiment of the present invention, there is provided a wavelength-variable laser including a semiconductor optical amplifier, the wavelength-variable laser including: a wavelength selection mechanism for selectively transmitting a predetermined wavelength; an isolator for transmitting light only in one direction; an SOA which is a semiconductor optical amplifier for amplifying light, the SOA being configured to amplify in an active layer light that enters a first end facet and to cause the amplified light to exit from a second end facet; and a ring optical waveguide for making connection so that light which exits from the second end facet of the SOA enters the first end facet, in which the second end facet of the SOA has a multilayer film formed thereon to enable control of a shape of a gain spectrum obtained in the entire SOA, the multilayer film having a reflectance which depends on wavelength.

According to another exemplary embodiment of the present invention, there is provided an optical coherence tomography apparatus for imaging a tomogram of a sample to be measured by interference of light emitted from a light source unit, the optical coherence tomography apparatus including the wavelength-variable laser according to the exemplary embodiment of the present invention as the light source unit.

Further features of the present invention will become apparent from the following description of exemplary embodiments with reference to the attached drawings.

### BRIEF DESCRIPTION OF DRAWINGS

FIG. 1A is a diagram illustrating an exemplary structure of a reflective SOA according to a first embodiment of the present invention, and is a diagram illustrating the vertical layer structure thereof.

FIG. 1B is a diagram illustrating the exemplary structure of the reflective SOA according to the first embodiment of the present invention, and is a diagram illustrating the device shape thereof.

FIG. 2 is a graph showing a reflectance spectrum realized in a multilayer film at a rear end facet of the SOA according to the first embodiment of the present invention.

FIG. 3 is a graph showing the dependence on carrier density of a gain spectrum of a quantum well according to the first embodiment of the present invention.

FIG. 4A is a graph showing a gain spectrum of a conventional SOA.

FIG. 4B is a graph showing a gain spectrum of the SOA according to the first embodiment.

FIG. 5 is a diagram illustrating an exemplary structure of an external resonator type laser including the SOA according to the first embodiment of the present invention.

FIG. 6 is a diagram illustrating an exemplary structure of an external resonator type laser including a transmissive SOA according to a second embodiment of the present invention.

FIG. 7 is a diagram illustrating the device shape of the transmissive SOA according to the second embodiment of the present invention.

FIG. 8 is a graph showing a reflectance spectrum of end facet coating applied to the SOA according to the second embodiment of the present invention.

FIG. 9A is a graph showing a gain spectrum of a conventional SOA.

FIG. 9B is a graph showing a gain spectrum of the SOA according to the second embodiment.

FIG. 10 is a diagram illustrating the device shape of a transmissive SOA according to a third embodiment of the present invention.

FIG. 11A is a graph showing a gain spectrum of an active layer of the SOA according to the third embodiment of the present invention.

FIG. 11B is a graph showing a reflectance spectrum of the active layer of the SOA according to the third embodiment of the present invention.

FIG. 12A is a graph showing a gain spectrum of a conventional SOA.

FIG. 12B is a graph showing a gain spectrum of the SOA according to the third embodiment.

### DESCRIPTION OF EMBODIMENTS

Preferred embodiments of the present invention will now be described in detail in accordance with the accompanying drawings.

According to the present invention, the shape of a gain spectrum itself of an SOA which is a semiconductor optical amplifier for amplifying light is not controlled but the shape of a gain spectrum obtained in the entire SOA is controlled to enable reduction of optical output fluctuations of the laser.

As described above, an SOA is used in an external resonator type laser or the like, and, in such an application, the gain spectrum of the SOA is required to be flattened. However, the shape of a spectrum of an SOA depends on the physical properties such as the carrier density distribution in an active layer, and thus, the shape cannot be arbitrarily controlled from the external.

Therefore, according to the present invention, the shape of the gain spectrum of a quantum well itself in the SOA is not controlled, but, as a device structure other than this, a multilayer film whose reflectance depends on wavelength of a wavelength band in which population inversion is caused under the driving conditions of the SOA is formed on one end facet of the SOA.

Specifically, the multilayer structure is placed on the one end facet of the SOA to cause the reflectance to be dependent on wavelength, thereby flattening the amplification factor of the entire device (hereinafter referred to as SOA gain).

At that time, by implementing the design so that the reflectance of the multilayer film formed on the end facet compensates for the shape of the gain spectrum under the driving conditions of the SOA, a more flattened SOA gain can be obtained.

### Embodiments

Embodiments of the present invention are described in the following.

### First Embodiment

As a first embodiment of the present invention, an exemplary structure of a wavelength-variable laser including a reflective SOA to which the present invention is applied is described.

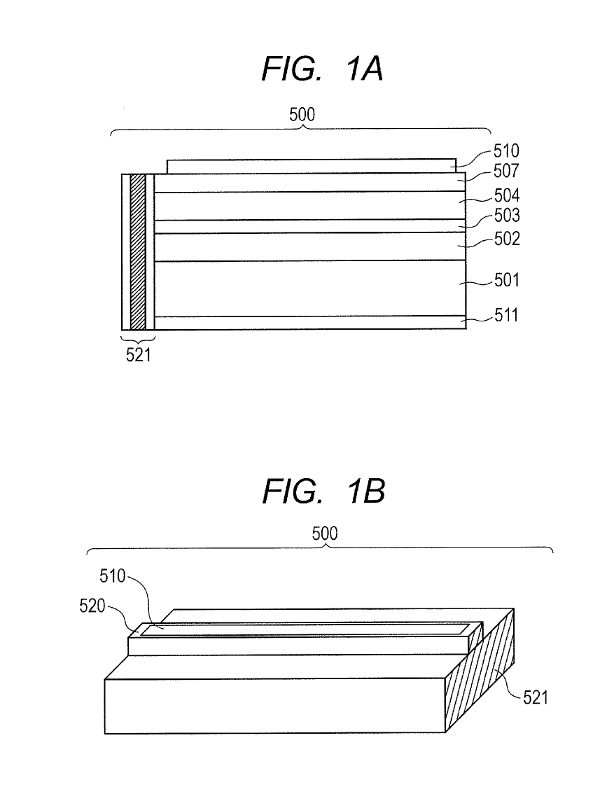

First, the reflective SOA in this embodiment is described with reference to FIG. 1A and FIG. 1B.

FIG. 1A is a diagram illustrating the structure of the reflective SOA in this embodiment.

FIG. 1A illustrates a reflective SOA 500 in this embodiment. The vertical layer structure of the SOA 500 in this embodiment is as follows.

An n-cladding layer 502 formed of Al_{0.5}Ga_{0.5}As is placed on a GaAs substrate 501.

An active layer 503 including one InGaAs/GaAs quantum well (not shown) is placed on the n-cladding layer 502.

The active layer 503 is formed of one quantum well layer, and the emission wavelength thereof from the ground level is 1,050 nm.

A p-cladding layer 504 formed of a p-type Al_{0.5}GaAs layer is placed on the active layer 503.

A contact layer 507 which is formed of heavily doped p-type GaAs and has thickness of 10 nm is placed on the p-cladding layer 504.

An upper electrode 510 in which electrical contact with the contact layer 507 is secured is provided on the contact layer 507.

A lower electrode 511 on the rear surface of the substrate, in which electrical contact with the substrate 501 is secured, is provided under the substrate 501.

FIG. 1B is a diagram illustrating the device shape of the SOA in this embodiment.

As illustrated in FIG. 1B, with regard to the device shape of the SOA 500, the p-cladding layer 504 and the contact layer 507 are partially removed up to midway of the p-cladding layer, and, as a remaining portion, a ridge-shaped portion 520 having a width of 4 μm is formed.

The device length is 0.4 mm, and the upper electrode 510 is formed on the ridge-shaped portion 520.

End facets of the ridge are cleaved facets of a GaAs crystal, and the waveguide direction of light which depends on the ridge structure and the GaAs cleaved facets are perpendicular to each other.

So-called AR coating (antireflection layer) for lowering the reflectance is applied to a front end facet (first end facet), and a multilayer film 521 for controlling a reflectance spectrum is added to a rear end facet (second end facet).

In this case, the front end facet refers to an end facet on an incident light side when, as in the SOA used in this embodiment, light which enters one end facet is taken out from the same end facet to be used. The rear end facet refers to the other end facet.

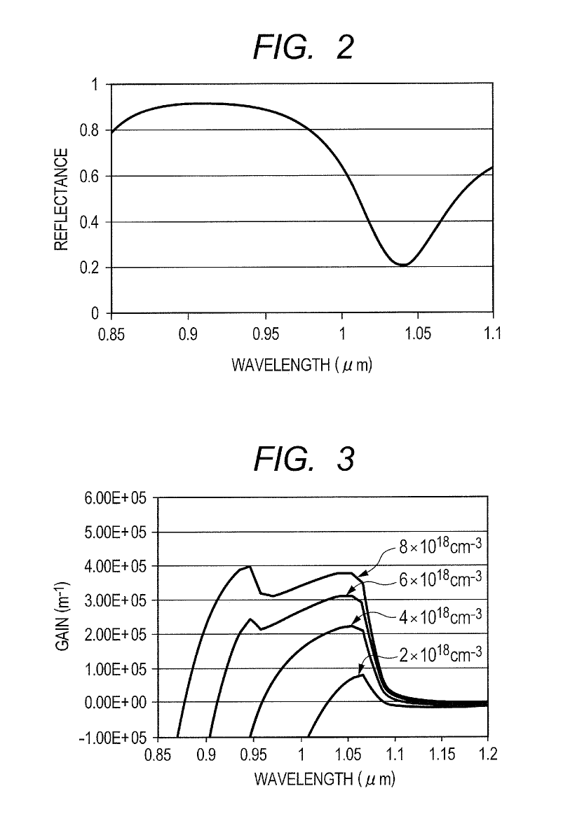

The multilayer film 521 is formed by stacking 5.5 pairs of SiO₂ having a refractive index of 1.5 and SiN having a refractive index of 1.7 as a distributed Bragg reflector (DBR) having a center wavelength of 900 nm. A gold thin film (10 nm) is stacked thereon. A reflectance spectrum realized by the multilayer film 521 is shown in FIG. 2.

FIG. 3 shows a gain spectrum of the active layer in this embodiment together with the dependence thereof on carrier density. Under a state in which the carrier density is low, light emission from a long wavelength side at about 1,050 nm from the ground level is observed. As the carrier density becomes higher, light emission at about 930 nm from the first-order level increases.

When the carrier density is about 6 to 8×10¹⁸ cm⁻³, the extents of these two modes of light emission are almost the same.

In this embodiment, the multilayer film 521 placed on the rear end facet has the reflectance spectrum shown in FIG. 2 so that, when the SOA is driven under the driving conditions in which the carrier density is 6×10¹⁸ cm⁻³, the spectrum output by the SOA becomes a more flattened gain spectrum. A specific design guideline is described later.

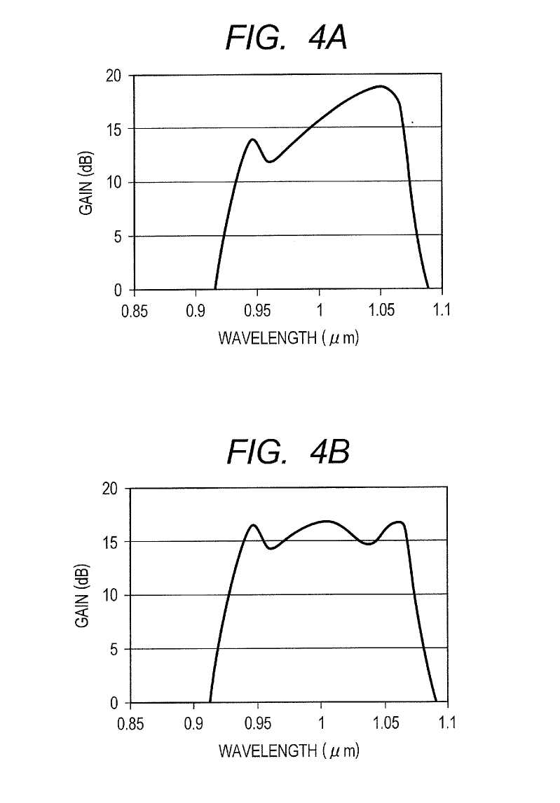

FIG. 4A and FIG. 4B show results of calculation of the SOA gain with regard to the SOA having such an device structure in a case of a reflecting mirror having a structure in which the reflectance at the rear end facet does not depend on wavelength (the reflectance is 0.5 and does not depend on wavelength) and in a case in which the rear end facet has a reflectance spectrum realized by the multilayer film 521 of this example, respectively. The reflectance at the rear end facet of the case shown in FIG. 4A is 0.5 irrespective of the wavelength.

On the other hand, FIG. 4B shows the case in which the above-mentioned multilayer film 521 is placed.

In FIG. 4A, the peak of the SOA gain is about the wavelength at the ground level, and the SOA gain becomes lower on the shorter wavelength side and the longer wavelength side.

This reflects the gain spectrum shown in FIG. 3. The gain band width in which the gain is −3 dB from the peak is 60 nm.

On the other hand, FIG. 4B shows the SOA gain which is affected by the reflectance distribution at the end facet.

When the multilayer film 521 is placed, the SOA gain is more flattened. The −3 dB bandwidth is 130 nm.

This makes it clear that, by placing the reflecting film according to the present invention on the SOA, the SOA gain can be flattened and the bandwidth can be increased.

The design guideline of the multilayer film 521 used for controlling the shape of the emission spectrum of the SOA is herein described. A basic guideline is to lower the reflectance at the wavelength of the peak gain under the driving conditions, such as at the ground level or at the first-order level, with the shape of the gain spectrum inherent in the quantum well. Further, it is preferred that the reflectance in a wavelength region in which the gain (induced amplification) is caused but is lower than the peak gain be caused to be relatively high. More preferably, the reflectance is close to 100%.

This can flatten the SOA gain obtained in the entire SOA device.

Further, by also using the spectrum band which decreases from the peak of the reflection spectrum of the DBR, the shape can be further flattened.

The width of the spectrum band in which the reflectance varies depends on the refractive index difference of the multilayer film which is placed. By increasing the refractive index difference, the reflectance may vary over a broader wavelength band.

The condition of the reflectance spectrum, under which the effect of the present invention can be obtained, is that, in a wavelength band in which not absorption but induced amplification action is caused, the reflectance at the rear end facet varies by 10% or more.

If the reflectance does not vary, amplification is performed over the entire wavelengths, and thus, the shape of the spectrum at the front end facet cannot be controlled.

Further, it is preferred that the peak of the reflectance be close to 100%. The reason is that, the peak exists at a wavelength at which the gain of the quantum well is low, and thus, it is necessary to increase the SOA gain as efficiently as possible, and, if the peak is lower than 100%, the SOA gain at the wavelength is lowered accordingly.

Further, it is desired that the reflectance of the AR coating on the front end facet be 5% or less in order to inhibit laser oscillation. When ripples in the resonator effect spectrum at the end facet are to be reduced, a further lower value is necessary.

The peak of the SOA gain varies depending on the driving conditions, and thus, is not determined uniquely, but, with regard to a single quantum well or multiple quantum wells having the same structure as in this embodiment, due to limitations such as heat saturation, the peak often appears at the ground level or at the first-order level thereabove.

Therefore, it is useful to set a valley of the reflectance at the rear end facet around the wavelength at the ground level or at the first-order level.

This can place a valley of the reflectance of the multilayer film formed on the rear end facet within 10 nm with respect to the wavelength at the ground level of the quantum well as the center and can flatten the SOA gain. Also in this embodiment, the valley of the reflectance at the rear end facet is placed at the wavelength at the ground level.

Specifically, as shown in FIG. 3, the gain spectrum has a peak at about 1,050 nm at the ground level, and, as shown in FIG. 2, the reflectance has a valley at about 1,050 nm.

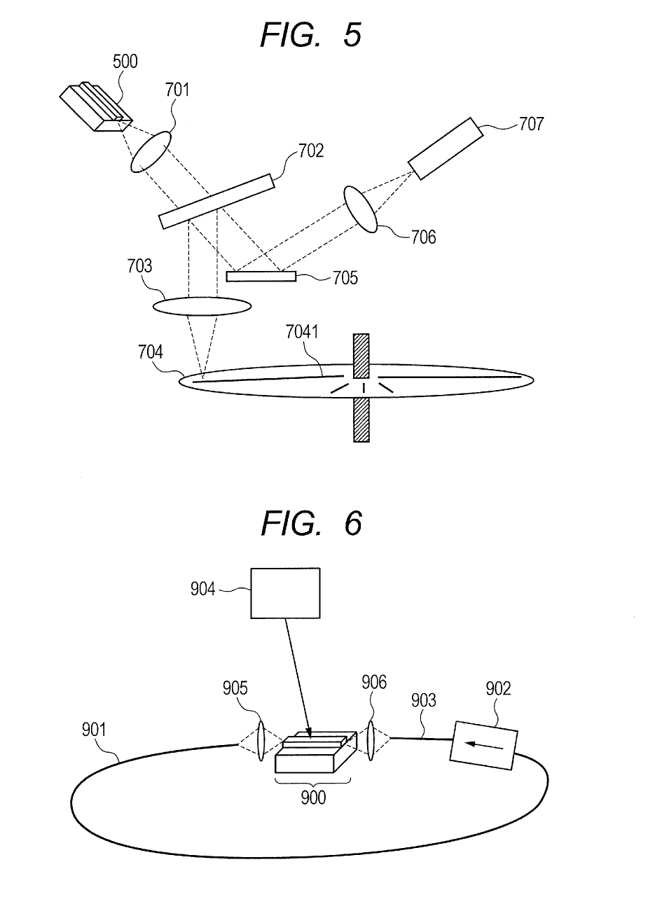

FIG. 5 illustrates an exemplary structure of an external resonator type laser including the above-mentioned SOA 500 in this embodiment.

In FIG. 5, the external resonator type laser includes the SOA 500, a collimator lens 701, a grating 702, a condensing lens 703, a rotary disk 704 including reflecting members, and a mirror 705. Light emitted from the SOA 500 is caused to be collimated light by the collimator 701 to enter the grating 702.

Light diffracted by the grating 702, which is dependent on wavelength, is condensed by the condensing lens 703 on the rotary disk 704.

Only a part of the rotary disk 704 including the reflecting members has a reflectance distribution, and only a part of reflecting members 7041 has a high reflectance.

Therefore, the condensing position of light diffracted by the grating 702 differs depending on the wavelength. Further, only a part of the rotary disk 704 has a high reflectance, and thus, only light having certain wavelengths is reflected. The reflected light passes through the condensing lens 703 and the grating 702 to return to the SOA 500.

In this way, the light returns, and a resonator is formed to cause the laser operation using the gain of the SOA 500.

Light which travels in a straight line without being diffracted by the grating 702 is reflected by the mirror (reflecting mirror) 705 to pass through a condensing lens 706 and enter an optical fiber 707. This light is used as output light from the laser.

In this embodiment, a portion which operates as a wavelength selection filter includes the grating 702, the condensing lens 703, and the rotary disk 704, but other wavelength selection structures are also possible.

Next, a method of manufacturing the SOA in this embodiment is described.

An actual procedure of manufacturing the device is as follows.

First, by organic metal vapor deposition or molecular beam epitaxy, a semiconductor layer structure including the n-cladding layer 502, the active layer 503, the p-cladding layer 504, and the contact layer 507 is grown on the GaAs substrate 501.

A dielectric film is formed by sputtering on the wafer. After that, a stripe forming mask for forming the ridge is formed of a photoresist using semiconductor lithography.

Portions of the semiconductor other than a portion covered with the stripe forming mask are selectively removed by dry etching to form a ridge shape having a height of 0.5 μm.

After that, SiO₂ is formed on the surface of the semiconductor, and SiO₂ on the ridge is partly removed by photolithography.

Then, the p-side and n-side electrodes 510 and 511 are formed using vacuum deposition and lithography.

In order to obtain satisfactory electrical properties, the electrodes and the semiconductor are alloyed in a high temperature nitrogen atmosphere.

Finally, crystal facets are produced at the end facets by cleavage, and each of the end facets is coated with a dielectric film for adjusting the reflectance. General AR coating is formed on the front end facet. The multilayer film 521 for controlling the reflectance spectrum, which is formed by stacking 5.5 pairs of SiO₂ having a refractive index of 1.5 and SiN having a refractive index of 1.7 as a DBR having a center wavelength of 900 nm, is formed on the rear end facet. These dielectric films are applied to the front and rear cleaved facets to complete the SOA device.

In this embodiment, the reflecting mirror at the rear end facet of the SOA is stacked on the end facet. Other than such a structure, there may be adopted a structure in which an optical thin film stacked on a glass plate or the like other than the SOA chip serves as the reflecting mirror and optical coupling is provided using a lens.

Similarly to the case of this embodiment, such a structure can also control the dependence of the amplification factor of the SOA on wavelength by the reflectance spectrum of the reflecting mirror.

However, in such a case, even if the reflectance of the stacked film is increased to 100%, it is practically difficult to cause the coupling efficiency to the waveguide of the SOA to be 100%.

The reason is that the transverse mode of emitted light is oval and it is difficult to cause close to 100% of the light to enter the effective diameter of the lens, and that it is difficult to cause the mode shape thereafter to be a shape similar to the shape of the waveguide mode of the SOA and return the light to the SOA so as to cause the mode coupling to be close to 100%. Therefore, practically, the coupling efficiency is about 80% at the maximum.

According to the present invention, the effect of the present invention differs significantly depending on the reflectance of light which can be returned to the waveguide of the SOA.

For example, compared with a case in which 100% of the light is coupled to the waveguide including the coupling efficiency, a case in which the coupling efficiency drops to 50% is equivalent to a case in which the gain obtained by the SOA is reduced by 50%. Specifically, the gain which the SOA chip originally has cannot be fully used as it is.

Further, in the case in which the reflecting mirror is provided outside in this way, when the low reflection layer at the end facet of the SOA is insufficient, a resonator is formed between the reflecting mirrors, and the original resonator and this resonator become a so-called coupled resonator, and thus, operation becomes unstable when the wavelength varies.

Further, also from the viewpoint of the cost and the mechanical stability, a structure in which the reflection layer is provided at the end of the SOA is desired.

### Second Embodiment

An exemplary structure of an external resonator type laser including a transmissive SOA according to a second embodiment of the present invention is described. In the first embodiment, the SOA operates as a reflective SOA in which light which enters the front end facet thereof is reflected by the rear end facet and the reflected light is taken out again at the front end facet.

On the other hand, the SOA of this example is a transmissive SOA in which light which enters one end facet exits from the other end facet, and the way that light enters and is taken out differs from that in the first embodiment.

Due to the difference between the reflective SOA and the transmissive SOA, the reflectance spectrum at the end facet in this embodiment is different from that in the first embodiment.

FIG. 6 illustrates an exemplary structure of an external resonator type laser including a transmissive SOA similar to that in this embodiment.

In this embodiment, there is formed a wavelength-variable laser which uses a fiber having a large wavelength dispersion as disclosed in, for example, NPL 2.

Such a laser is known as a ring wavelength-variable laser, and has a structure described below.

That is, the laser includes a wavelength selection mechanism for selectively transmitting a predetermined wavelength, an isolator for transmitting light only in one direction, and an SOA for amplifying light, which is configured to amplify in an active layer thereof light that enters the first end facet and to emit the amplified light from the second end facet. Connection is made by an optical waveguide so that light which exits from the second end facet of the SOA enters the first end facet.

In this embodiment, the above-mentioned wavelength selection mechanism, isolator, and SOA include a transmissive SOA 900, a dispersion fiber 901, an isolator 902, a fiber 903, an SOA drive circuit 904, and lenses 905 and 906 for optically coupling the fiber and the SOA.

The operating principle of this embodiment uses, as disclosed in NPL 2 and the like, the fact that the time taken for going around the resonator varies depending on the wavelength.

By periodically changing the gain and the loss in the SOA or the like in accordance with the time taken for going around, oscillation takes place only with regard to the wavelength corresponding to the period.

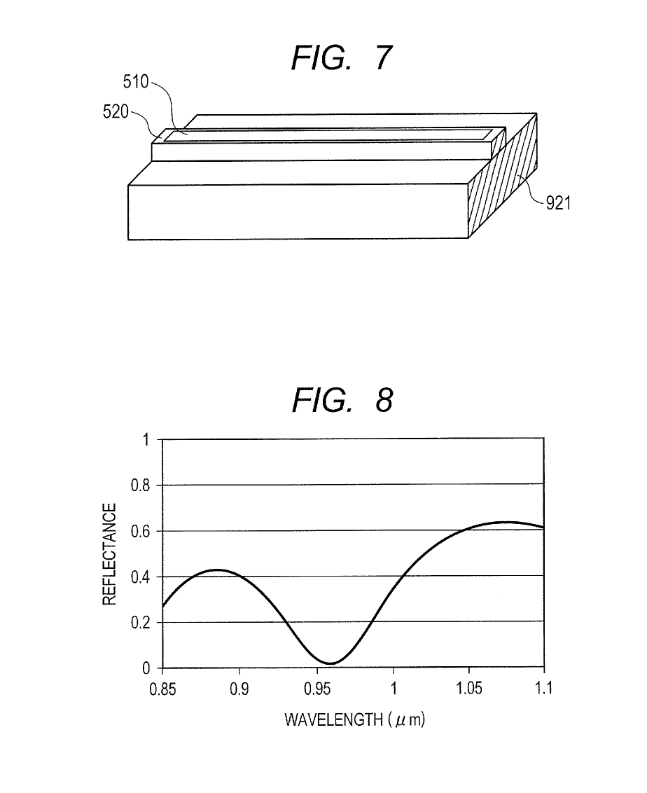

An exemplary structure of the SOA according to this embodiment is described with reference to FIG. 7.

The semiconductor layer structure of the SOA according to this embodiment is the same as that in the first embodiment. Therefore, detailed description of the layer structure is omitted. However, a multilayer film 921 placed on an end facet is different from that in the first embodiment.

The multilayer film 921 has a DBR structure which has a center wavelength of 1,080 nm and which is formed of 5 pairs of two kinds of optical thin films, i.e., SiO₂ having a refractive index of 1.5 and SiON having a refractive index of 1.6. The optical thickness of each of the two kinds of optical thin films is ¼ of the center wavelength.

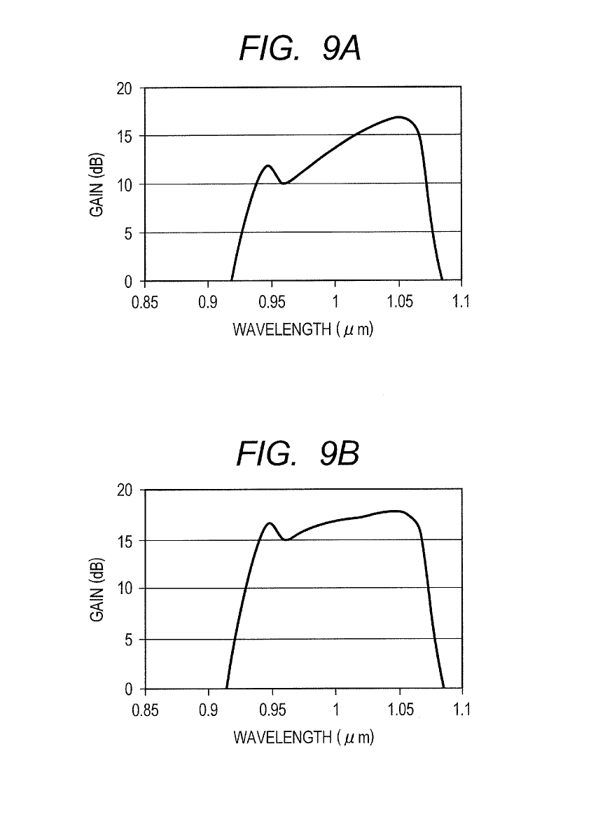

FIG. 8 shows a reflectance spectrum realized by this structure. FIG. 9B show the results of calculation of the SOA gain in this embodiment.

The driving conditions of the SOA in this embodiment is the same as those in the first embodiment, in which the carrier density is 6×10¹⁸ cm⁻³.

FIG. 9A shows the SOA gain under operating conditions in which the reflectance at both end facets is zero. On the other hand, FIG. 9B shows the case in which the above-mentioned multilayer film 921 is placed.

In FIG. 9A, the peak of the gain is about the wavelength at the ground level, and the gain becomes lower on the shorter wavelength side and the longer wavelength side.

This reflects the gain spectrum shown in FIG. 3. The gain band width in which the gain is −3 dB from the peak is 60 nm.

On the other hand, FIG. 9B shows the gain which is affected by the reflectance distribution at the end facet under the driving conditions.

When the multilayer film 921 is placed, the SOA gain is more flattened. The −3 dB bandwidth is 130 nm. This makes it clear that, by placing the reflecting film according to the present invention on the SOA, the SOA gain can be flattened and the bandwidth can be increased.

In a transmissive SOA as in this embodiment, the reflectance of the end facet coating is increased with regard to a wavelength at which the active layer gain is high.

This is for the purpose of, with regard to a wavelength at which the active layer gain is high, by reducing the amount of light which passes through the SOA when light enters the end facet of the SOA, causing the amplification factor after the light passes through the SOA to be closer to that at a wavelength at which the active layer gain is low.

As a result, the dependence of the SOA gain on wavelength is reduced. The reflected light is absorbed by the isolator 902. This can inhibit oscillation by light which travels in the reverse direction by reflection.

In this embodiment, the multilayer film 921 having a reflectance distribution is placed on the end facet on the light incident side of the SOA (side closer to the isolator), and the opposite end facet on the light exit side has AR coating applied thereto.

When the structure is opposite thereto, specifically, when the end facet on the incident side has AR coating and the end facet on the exit side has coating having a reflectance distribution, the effects are different. Specifically, when the end facet on the exit side has a reflectance distribution, light at a wavelength at which the reflectance is high passes through the SOA in one direction once and in the other direction once, and then, enters the isolator.

When the SOA is driven in a state in which so-called spectral hole burning is caused, the reflected light consumes carriers around the wavelength of the reflected light to reduce the gain with regard to the wavelength. Therefore, compared with the above-mentioned case, even when a reflection layer having the same reflectance is placed, a greater change in amplification factor can be caused.

As described in the first embodiment, instead of applying the multilayer coating to the end facet for causing the end facet to have a reflectance spectrum, also in a method of causing light to pass through a filter on which a multilayer film is stacked and to enter the SOA, or a method in which a refractive index distribution is caused in the optical fiber to cause a reflectance distribution, the effect can be obtained to some extent.

However, when a multilayer filter is stacked on a glass plate or the like, it is necessary to cause light to exit from the fiber and to couple the light to the optical fiber or the end facet of the SOA again after passage of the filter. In that case, as described in the first embodiment, it is practically difficult to increase the coupling efficiency of the light close to 100%. Therefore, even with regard to a wavelength band in which the gain of the quantum well is low, loss of light occurs, and thus, compared with a case in which the multilayer mirror is placed on the end facet as in this embodiment, the SOA gain is lowered as a whole.

On the other hand, when a refractive index distribution is caused in the optical fiber and is used for a reflectance distribution, such loss of light in coupling does not occur.

However, the refractive index difference which can be made in the optical fiber is small, and thus, the wavelength band in which the reflectance can be controlled is narrow. Specifically, the wavelength band is 2 nm or less.

On the other hand, with regard to the band necessary in the present invention, as is apparent from FIG. 2 and FIG. 8, not until the reflectance is changed over a band of several tens of nanometers, the wavelength can be stably varied over a wide band, which is the object to be achieved by the present invention.

Therefore, it is difficult to apply a general fiber grating as it is. Further, according to the present invention, the SOA chip and the multilayer film are integral, and thus, there are advantages that mechanical misalignment and instability of properties caused thereby are prevented and the cost can be reduced.

### Third Embodiment

As a third embodiment of the present invention, an exemplary structure is described in which the structure of the quantum well layer is different from that in the first embodiment.

This embodiment is different from the first embodiment in that the semiconductor layer structure has, as the quantum well layer, a structure which is called an asymmetric quantum well or a modulated quantum well. This embodiment is similar to the first embodiment in that the SOA is designed as a reflective SOA.

In this embodiment, there are used two quantum wells having different emission wavelengths at the ground level. The emission wavelengths of the quantum wells are 1,050 nm and 930 nm, respectively.

In the structure, at an injection current value at which carriers are accumulated in the 1,050 nm quantum well at a density of 5×10¹⁸ cm⁻³, carriers are accumulated in the 930 nm quantum well at a density of 3×10¹⁸ cm⁻³. In this embodiment, this state is the driving conditions of the device.

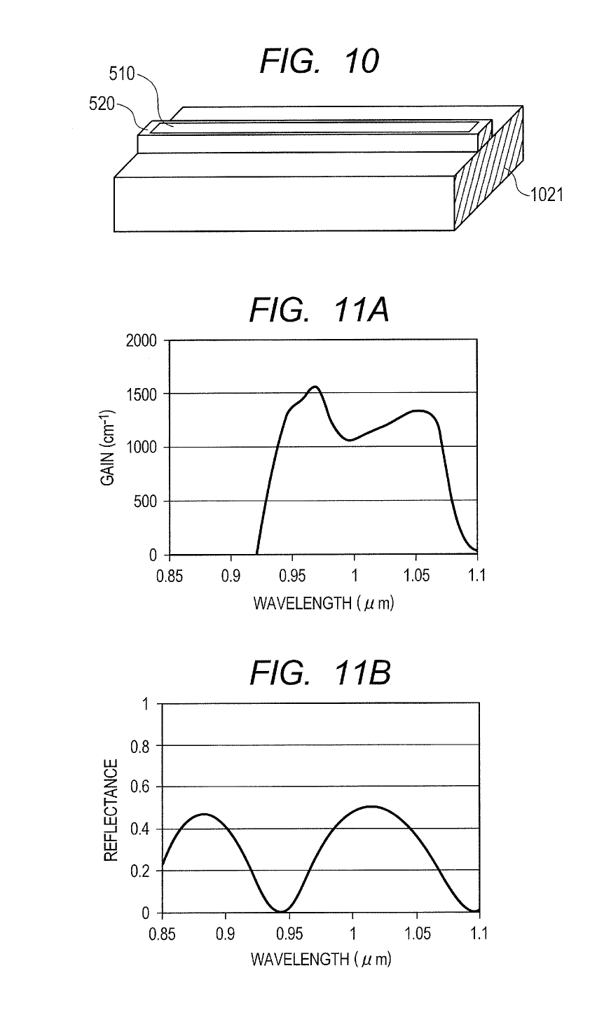

Further, a multilayer film 1021 on the rear end facet illustrated in FIG. 10 has a center wavelength of 980 nm. The multilayer film has a DBR structure, and is formed of two kinds of films which have a refractive index of 1.5 and a refractive index of 1.51, respectively. The refractive index of 1.5 is realized by SiO₂, while the refractive index of 1.51 is realized by SiON.

In the asymmetric quantum well, the number of the carriers in the quantum well on the short wavelength side may be controlled to be smaller than that in the quantum well on the long wavelength side by using a phenomenon that narrowing the width of the quantum well raises the ground level and reduces the transition rate from a barrier layer to a well layer.

FIG. 11A and FIG. 11B show the gain of the asymmetric quantum well layer and the reflectance of the multilayer film, respectively, under the driving conditions of this device.

FIG. 11A shows the gain spectrum of the asymmetric quantum well. Two peaks correspond to the ground levels of the quantum wells, respectively.

FIG. 11B shows the reflectance spectrum of the multilayer film.

A region in which the reflectance is low is placed at a peak of the gain. This viewpoint is similar to those in the first and second embodiments.

However, in this embodiment, there are multiple peaks which have gains to similar extents, and thus, the refractive index difference between the two kinds of films forming the DBR is reduced so that the reflectance is low at both of these peaks.

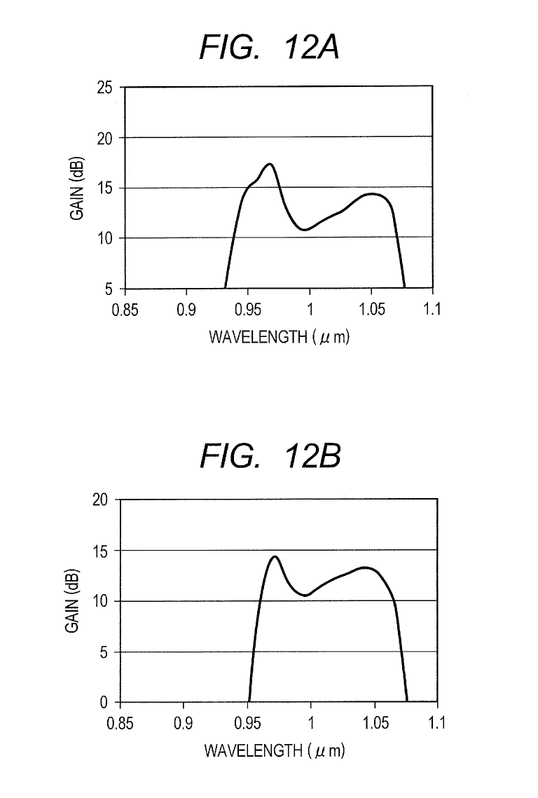

FIG. 12A and FIG. 12B show the results of calculation of the SOA gain spectra in a case of the reflecting mirror having a structure in which the reflectance at the rear end facet does not depend on wavelength and in a case in which the rear end facet has a reflectance spectrum realized by the multilayer film 1021 of this embodiment, respectively.

FIG. 12A shows the case in which the reflectance at the rear end facet is constant irrespective of the wavelength, and FIG. 12B shows the case in which the multilayer film 1021 having a center wavelength of 980 nm is used.

When a comparison is made between FIG. 12A and FIG. 12B, the difference between a peak and a dip is smaller in FIG. 12B.

In FIG. 12A, the difference between the peak when the wavelength is 970 nm and the dip when the wavelength is 1,000 nm is 6.4 dB. On the other hand, in FIG. 12B, the difference between the peak and the dip is 3.9 dB. As described above, even in an SOA into which an asymmetric quantum well is introduced, by controlling the reflectance spectrum of the end facet coating, the shape of the spectrum of light emitted from the SOA can be controlled, and the shape of the spectrum can become closer to a shape which is required by each application.

Also when an asymmetric quantum well as in this embodiment is used, light emission around the levels of the quantum wells can be enhanced, and, compared with a structure in which a single quantum well layer or multiple same quantum well layers having the same structure are used, the active layer gain can be more flattened.

However, light emission between these levels cannot be selectively enhanced.

This is because, as described above, the shape of the gain spectrum of each of the quantum wells is determined, and the shape of the SOA spectrum depends on the combination thereof.

Therefore, in order to further flatten the gain spectrum in such a case, the present invention is particularly effective.

Note that, in this embodiment, an asymmetric quantum well is used, and thus, light emission from only the zero-order levels of the quantum wells can cover a wide wavelength band.

Therefore, the carrier density under the driving conditions is at a lower level compared with that in the first embodiment, which results in increased lifetime and reliability of the device.

In this embodiment, a peak of the reflectance is between two ground levels.

However, even when three or more quantum wells are introduced in which the ground levels thereof have different wavelengths, it is desired to provide a peak and a valley of the reflectance at the rear end facet in a wavelength band between the ground level of the shortest wavelength and the ground level of the longest wavelength.

The reason is that induced amplification is caused by formation of population inversion mainly in the wavelength band between the ground levels, and thus, by increasing the change in reflectance therein, dependence of the reflectance on wavelength can be provided in the wavelength band in which the induced amplification is caused, and the SOA gain spectrum can be effectively controlled. When the active layer has a quantum well structure, the above-mentioned range of the wavelength in which the induced amplification is caused can be translated into the range between the level of the longest wavelength among the ground levels of the quantum wells forming the active layer and the level of the shortest wavelength among the first-order levels of the quantum wells.

This is because, as can be seen from FIG. 3, in a quantum well structure, it is possible to accumulate the carriers and cause population inversion up to the first-order level with a practical carrier density.

On the other hand, even if secondary and higher levels exist, it is not practical to cause population inversion and cause induced amplification at the wavelengths.

Therefore, in the case of an active layer having a quantum well structure, when a region in which the reflectance changes significantly exists in the above-mentioned wavelength range, specifically, between the wavelength at the level of the shortest wavelength among the first-order levels and the wavelength at the level of the longest wavelength among the ground levels, the SOA gain can be controlled.

It is preferred that, in this range, with change in reflectance by 20% or more from the peak, the emission spectrum of the SOA can be effectively changed.

Further, in the first embodiment to the third embodiment, the SOA is formed on a GaAs substrate, but the effect of the present invention can be similarly obtained in SOAs which are formed on an InP substrate or a GaN substrate and which is composed of other materials.

Therefore, the present invention is not limited to an SOA formed on a GaAs substrate. Similarly, the emission wavelength band of the active layer is not limited to 1,050 nm.

Further, the active layer structure is a quantum well structure which is most effective with regard to an SOA, but the present invention is not limited thereto.

A confinement structure other than a quantum well structure, such as a bulk structure, a quantum wire structure, or a quantum dot structure, is also possible. In this case, it is necessary that a peak of the reflectance spectrum at the rear end facet be within the wavelength range in which a gain is caused in the active layer under the driving conditions of the SOA.

### INDUSTRIAL APPLICABILITY

According to the present invention, there can be realized a wavelength-variable laser including an SOA which controls not the shape of a gain spectrum itself of the SOA but the shape of a gain spectrum obtained in the entire SOA and which enables inhibition of optical output fluctuations of the laser.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-116552, filed May 22, 2012, which is hereby incorporated by reference herein in its entirety.

### REFERENCE SIGNS LIST

500: SOA
501: GaAs substrate
502: n-cladding layer
503: active layer
504: p-cladding layer
507: contact layer
510: upper electrode
511: lower electrode
520: ridge-shaped portion
521: multilayer film

1. A wavelength-variable laser including an SOA, the wavelength-variable laser comprising:
a wavelength selection mechanism for selectively reflecting a wavelength;
an SOA which is a semiconductor optical amplifier for amplifying light, the SOA being configured to reflect light that enters a first end facet by a second end facet opposite to the first end facet and to cause light amplified in an active layer to exit from the first end facet again; and
a reflecting member provided outside the SOA, the reflecting member forming a resonator in a pair with the second end facet for reflecting the light which enters,
wherein the second end facet of the SOA, which is on a side of reflecting the light, has a multilayer film formed thereon to enable control of a shape of a gain spectrum obtained in the entire SOA, the multilayer film having a reflectance which depends on wavelength.

2. The wavelength-variable laser including an SOA according to claim 1, wherein:
the multilayer film comprises a multilayer mirror stacked in a waveguide direction of light; and
the reflectance realized by the multilayer mirror changes by 10% or more in a wavelength band in which induced amplification action is caused in the active layer under driving conditions of the SOA.

3. The wavelength-variable laser including an SOA according to claim 2, wherein the reflectance realized by the multilayer mirror is relatively higher in a wavelength region in which the induced amplification action is small compared with the reflectance in a wavelength region in which the induced amplification action is large.

4. The wavelength-variable laser including an SOA according to claim 1, wherein the first end facet has an antireflection layer applied thereto, the antireflection layer having a reflectance of 5% or less.

5. The wavelength-variable laser including an SOA according to claim 1, wherein the active layer comprises a quantum well.

6. The wavelength-variable laser including an SOA according to claim 5, wherein:
the active layer comprises one of a single quantum well and multiple quantum wells having the same structure; and
a valley of the reflectance of the multilayer film formed on the second end facet is placed within 10 nm with respect to a wavelength at a ground level of the quantum well, which serves as a center.

7. The wavelength-variable laser including an SOA according to claim 5, wherein:
the active layer comprises multiple quantum wells in which multiple ground levels thereof have different wavelengths; and
a valley of the reflectance of the multilayer film formed on the second end facet is placed within 10 nm with respect to a wavelength at least one of the multiple ground levels.

8. The wavelength-variable laser including an SOA according to claim 1, wherein the SOA is formed on a GaAs substrate.

9. A wavelength-variable laser including an SOA, the wavelength-variable laser comprising:
a wavelength selection mechanism for selectively transmitting a predetermined wavelength;
an isolator for transmitting light only in one direction;
an SOA which is a semiconductor optical amplifier for amplifying light, the SOA being configured to amplify in an active layer light that enters a first end facet and to cause the amplified light to exit from a second end facet; and
a ring optical waveguide for making connection so that light which exits from the second end facet of the SOA enters the first end facet,
wherein the second end facet of the SOA has a multilayer film formed thereon to enable control of a shape of a gain spectrum obtained in the entire SOA, the multilayer film having a reflectance which depends on wavelength.

10. The wavelength-variable laser including an SOA according to claim 9, wherein:
the multilayer film comprises a multilayer mirrnor stacked in a waveguide direction of light; and
the reflectance realized by the multilayer mirror changes by 10% or more in a wavelength band in which induced amplification action is caused in the active layer under driving conditions of the semiconductor optical amplifier.

11. The wavelength-variable laser including an SOA according to claim 10, wherein the reflectance realized by the multilayer mirror is relatively higher in a wavelength region in which the induced amplification action is small compared with the reflectance in a wavelength region in which the induced amplification action is large.

12. The wavelength-variable laser including an SOA according to claim 9, wherein the first end facet has an antireflection layer applied thereto, the antireflection layer having a reflectance of 5% or less.

13. The wavelength-variable laser including an SOA according to claim 9, wherein the active layer comprises a quantum well.

14. The wavelength-variable laser including an SOA according to claim 13, wherein:
the active layer comprises one of a single quantum well and multiple quantum wells having the same structure; and
a peak of the reflectance of the multilayer film formed on the second end facet is placed within 10 nm with respect to a wavelength at a ground level of the quantum well, which serves as a center.

15. The wavelength-variable laser including an SOA according to claim 13, wherein:
the active layer comprises multiple quantum wells in which multiple ground levels thereof have different wavelengths; and
a peak of the reflectance of the multilayer film formed on the second end facet is placed within 10 nm with respect to a wavelength at least one of the multiple ground levels.

16. An optical coherence tomography apparatus for imaging a tomogram of a sample to be measured by interference of light emitted from a light source unit, the optical coherence tomography apparatus comprising the wavelength-variable laser according to claim 1 as the light source unit.
